(19) United States
(12) Patent Application Publication
(10) Pub. No.: US 2016/0264015 A1
(43) Pub. Date: Sep. 15, 2016

(54) VOLTAGE MEASUREMENT CIRCUIT

(71) Applicant: CALSONIC KANSEI CORPORATION, Saitama (JP)

(72) Inventor: Yasuhiro Kobayashi, Saitama (JP)

(21) Appl. No.: 14/442,556

(22) PCT Filed: Oct. 7, 2013
(86) PCT No.: PCT/JP2013/077245

§ 371 Date: May 13, 2015

(30) Foreign Application Priority Data
Nov. 15, 2012 (JP) 2012-250890

(51) Int. Cl. B60L 11/18; G01R 19/00

(52) U.S. Cl. CPC B60L 11/1861; G01R 19/0084

(57) ABSTRACT

A voltage measurement circuit, which can reduce a withstand voltage of each of voltage dividing resistors for voltage measurement, with respect to a surge voltage generated at the time of turning-on of a dark-current reduction relay, thereby enabling cost reduction, is provided. The voltage measurement circuit includes: a high-voltage input terminal; a plurality of voltage dividing resistors which divide a high voltage; a voltage measuring part which measures a voltage reduced to a low voltage by the plurality of voltage dividing resistors; and a dark current reduction relay which is connected in series between adjacent ones of the plurality of voltage dividing resistors.

### TECHNICAL FIELD

The present invention relates to voltage measurement circuits.

### BACKGROUND ART

A voltage measurement circuit described in a patent document 1 is known as an example of voltage measurement circuits of a related art. This voltage measurement circuit divides a voltage of a battery, used as a power source of an electric car or a hybrid car, by using a plurality of voltage dividing resistors, and measures a voltage of the battery

A circuit of a related art described in a patent document 2 is configured as follows. That is, a first keep relay is installed between a battery and electronic control devices needing to cut off a dark current. A second keep relay is installed between the battery and electronic control devices not needing to cut off the dark current. A voltage dividing resistor is installed on a wiring for connecting the respective electronic control devices. In the case an ignition switch is not turned on for a long period of time, the first keep relay is cut off to prevent battery exhaustion due to the dark current. In the case an over-current is generated in each of the electronic control devices, this is detected by the voltage dividing resistor, and the respective keep relays are cut off. Thus, damage of a circuit and a wiring caused by the over-current can be prevented.

### RELATED DOCUMENTS

### Patent Documents

Patent Document 1: JP-A-2010-19603

Patent Document 2: JP-A-2003-40050

### SUMMARY OF THE INVENTION

### Problems that the Invention is to Solve

However, the voltage measurement circuits of the related art have a problem explained below.

That is, the patent document 1 discloses the voltage measurement circuit in which a high voltage of the battery is reduced by using the voltage dividing resistors and then the voltage is measured. The patent document 2 discloses that, to reduce the dark current, the dark-current reduction relay is inserted between the battery and the voltage dividing resistor. The combination of this voltage measurement circuit and this dark-current reduction relay has been used.

In this combination, surge voltage is generated at the time of turning-on of the dark-current reduction relay, and this surge voltage is applied to the resistor at the highest voltage side. Thus, this resistor is required to have a high withstand voltage.

As a result, there arises a problem that an expensive resistor is obliged to use and hence the voltage measurement circuit becomes expensive.

The invention has been contrived bearing in mind the aforesaid problem, and has its object to provide a voltage measurement circuit which can reduce a withstand voltage of each of voltage dividing resistors for voltage measurement, with respect to a surge voltage generated at -the time of turning-on of a dark-current reduction relay, thereby enabling cost reduction of the voltage measurement circuit.

### Means for Solving the Problems

In order to attain this object, a voltage measurement circuit according to the invention includes:

a high-voltage input terminal;

a plurality of voltage dividing resistors which divide a high voltage inputted from the high-voltage input terminal;

a voltage measuring part which measures a voltage reduced to a low voltage by the plurality of voltage dividing resistors; and

a dark-current reduction switch circuit which is connected in series between adjacent ones of the plurality of voltage dividing resistors.

### Advantages of the Invention

In the voltage measurement circuit according to the invention, a dark current reduction relay is connected in series between adjacent ones of the plurality of voltage dividing resistors. Thus, a surge voltage generated at the both ends of the voltage dividing resistor, at the time of turning-on of the dark-current reduction relay, can be made small. As a result, the voltage dividing resistor, withstand voltage of which is reduced by an amount equivalent to the reduced amount of the surge voltage, can be used Accordingly, the cost of the voltage measurement circuit can be reduced.

### BRIEF DESCRIPTION OF THE DRAWINGS

FIG. 1 is a diagram showing a voltage measurement circuit according to a first embodiment of the invention.

FIGS. 2A to 2C are diagrams showing, in a comparative manner between a related art and the first embodiment, change of a voltage across the both ends of each of first and second voltage dividing resistors disposed near a dark-current reduction relay, at a time of turning-on of the dark current reduction relay.

FIGS. 3A to 3D are diagrams showing, in a comparative manner between the related art and the first embodiment wherein the position of the dark current reduction relay is changed, a surge voltage of the dark current reduction relay, at a time of turning-on of the dark current reduction relay.

### MODES FOR CARRYING OUT THE INVENTION

Hereinafter, an exemplary embodiment according to the invention will be explained in detail based on an embodiment shown in drawings.

### First Embodiment

Firstly, explanation will be given of an entire configuration of a voltage measurement circuit according to the first embodiment.

The voltage measurement circuit according to the first embodiment is a circuit which measures a total voltage of a battery mounted in an electric car or a hybrid car.

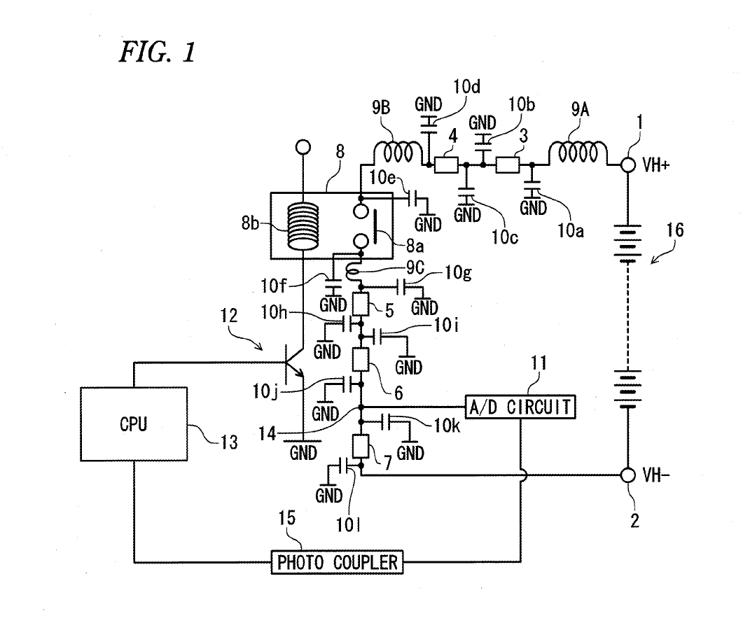

As shown in FIG. 1, the voltage measurement circuit according to the first embodiment is configured in a manner that a positive electrode side terminal 1 is connected to the positive electrode terminal (VH+) of a battery 16 and a negative electrode side terminal 2 is connected to the negative electrode terminal (VH−) of the battery 16.

A well-known high-voltage secondary battery, configured of serially connected many cells, is used as the battery 16. The positive electrode side terminal 1 (high-voltage input terminal) is connected to the battery of an electric car or a hybrid car.

A plurality of voltage dividing resistors (configured of five voltage dividing resistors, that is, a first voltage dividing resistor 3, a second voltage dividing resistor 4, a third voltage dividing resistor 5, a fourth voltage dividing resistor 6 and a fifth voltage dividing resistor 7 toward the negative electrode side terminal 2 from the positive electrode side terminal 1, in this embodiment) and a dark-current reduction relay 8 are connected in series between the positive electrode side terminal 1 and the negative electrode side terminal 2. Each of the voltage dividing resistors is configured of a thin film resistor, for example.

The dark-current reduction relay 8 is connected at the center or a portion close to the center of the plurality of voltage dividing resistors. More specifically, in the first embodiment, the dark-current reduction relay is connected in series between the second voltage dividing resistor 4 and the third voltage dividing resistor 5.

The dark-current reduction relay 8 corresponds to a dark current reduction switch circuit according to the invention.

In a circuit, a wiring has an inductance. The longer the wiring, the larger the inductance becomes. A magnitude of surge voltage depends on the position of the wiring.

In this respect, a length of each wiring is set to be small so as to reduce an inductance of the each wiring as possible. The inductance differs depending on the position of the wiring as explained below.

Firstly, a wiring between the positive electrode side terminal 1 and the first voltage dividing resistor 3 becomes inevitably long, and hence an inductance 9A therebetween becomes large.

Next, although the dark-current reduction relay 8 and the second voltage dividing resistor 4 are connected via a wiring of a short length as possible, this wiring is required to have a certain length. An inductance 9B of this wiring is smaller than the inductance 9A, but the magnitude of surge voltage can not be ignored.

A wiring between the dark-current reduction relay 8 and the third voltage dividing resistor 5 can be made short. Thus, an inductance 9C of this wiring is quite small as compared with the inductances 9A and 9B.

A wiring between the first voltage dividing resistor 3 and the second voltage dividing resistor 4 can be made short. Also, a wiring between the third voltage dividing resistor 5 and the fourth voltage dividing resistor 6 can be made short. Although each of these wirings has an inductance almost same as the inductance 9C, influence of each of these inductances on surge voltage is small. These inductances are not shown in FIG. 1 because these inductances become hard to see in the figure.

A divided voltage extraction part 14 is provided between the fourth voltage dividing resistor 6 and the fifth voltage dividing resistor 7. Thus, an inductance of a wiring between these resistors is larger than the inductance 9C but influence of this inductance on surge voltage is small. This inductance is also not shown in FIG. 1 because this inductance becomes hard to see in the figure.

A wiring between the fifth voltage dividing resistor 7 and the negative electrode side terminal 2 is long and hence an inductance of this wiring is large. However, influence of this inductance on surge voltage is small. This inductance is also not shown in the figure.

A voltage thus divided by the resistors is taken out from the divided voltage extraction part 14 as a divided voltage, lower than 5 volts, of the total voltage and then applied to an A/D circuit 11.

As shown in FIG. 1, stray capacitances 10a to 10l exist at the both sides of the voltage dividing resistors 3 to 7 and the both sides of a mechanical contact 8a.

In this case, each of the stray capacitances 10e and 10f at the both sides of the mechanical contact 8a is smaller than the stray capacitances 10a to 10d and 10g to 10l of the voltage dividing resistors 3 to 7.

The dark-current reduction relay 8 is configured of the mechanical contact 8a and an electromagnet 8b. One end of the electromagnet 8b is connected to a power source of 5 volts, and the other end thereof is connected to the collector of a transistor 12.

In the transistor 12, the collector is connected to the electromagnet 8b as described above, an emitter is grounded and a base is connected to a central processing unit (CPU) 13. The CPU 13 controls the operation of the transistor.

The voltage taken out from the divided voltage extraction part 14 as the divided voltage of the total voltage is converted into a digital signal by the A/D circuit 11 and sent to a photo coupler 15. The digital signal is converted into an optical signal by the photo coupler and inputted to the CPU 13 via a not-shown optical cable.

The CPU 13 converts the optical signal into a digital signal and calculates a voltage of the battery 16.

As described above, the A/D circuit 11, the photo coupler 15 and the CPU 13 act as a voltage measuring part which measures a voltage reduced to a low voltage by the plurality of voltage dividing resistors.

An action of the voltage measurement circuit according to the first embodiment configured in this manner will be explained. Firstly, explanation will be given of a reason why a large surge voltage is generated in the related art.

In the related art, five voltage dividing resistors, that is, first to fifth voltage dividing resistors are serially disposed at the downstream side of the dark-current reduction relay 8. A wiring connecting between the upstream side of the dark-current reduction relay 8 and the positive electrode side terminal 1 becomes inevitably long, and hence an inductance (hereinafter briefly a first inductance) of this wiring becomes large.

In the circuit of the related art, the wiring connecting between the upstream side of the dark-current reduction relay 8 and the positive electrode side terminal 1 has a first stray capacitance. A wiring between the downstream side of the dark-current reduction relay 8 and the first voltage dividing resistor disposed on the downstream side of the dark-current reduction relay has a second stray capacitance.

In the turn-off state of the dark-current reduction relay 8, a large voltage of several hundred volts (400 volts, for example) of the battery 16 is applied to the first stray capacitance, whilst 0 volt is applied to the second stray capacitance. When the dark-current reduction relay 8 is turned on, rush current instantaneously flows through the wiring of the large first inductance which is disposed between the upstream side of the dark-current reduction relay 8 and the positive electrode side terminal 1.

As a result, electric charge having been accumulated in the first stray capacitance is charged in the second stray capacitance through the wring of the first inductance, connecting between the dark-current reduction relay 8 and the positive electrode side terminal 1, and the wiring of a second inductance, connecting between the dark-current reduction relay 8 and the first voltage dividing resistor. The first inductance is quite larger than the second inductance.

When the electric charge is accumulated in the second stray capacitance, the rush current disappears. Then, electromotive voltage according to the first and second inductances is generated. Current continues to flow to thereby charge the second stray capacitance due to the electromotive voltage, and hence the voltage of the second stray capacitance increases.

Instantaneous temporal change of voltage values at the both sides of the first voltage dividing resistor will be explained. When the dark-current reduction relay 8 is turned on, the terminal voltage on the upstream side of the first voltage dividing resistor becomes equal to the electromotive voltage, and the terminal voltage on the upstream side of the first voltage dividing resistor becomes 0.

Thus, a resistor, that can withstand the high electromotive voltage generated by these inductances, is required to be used as the first voltage dividing resistor, which results in a cost increase.

To solve this problem, the voltage measurement circuit according to the first embodiment is configured to reduce electromotive voltage applied to the voltage dividing resistor when the dark-current reduction relay 8 is turned on. In this case, although each of the first inductance and the second inductance is required to be made small, it is difficult to further shorten the wiring on the second inductance side so as to reduce the second inductance. Further, as the second inductance is quite small as compared with the first inductance, the first inductance is made small in the first embodiment. However, in this case, it is impossible to merely shorten the length of the wiring on the first inductance side and so the length thereof can not be changed from that of the related art.

According to the first embodiment, as described above, the first voltage dividing resistor 3 and the second voltage dividing resistor 4 are disposed in series on the upstream side of the dark-current reduction relay 8. Further, the third voltage dividing resistor 5, the fourth voltage dividing resistor 6 and the fifth voltage dividing resistor 7 are disposed in series on the downstream side of the dark-current reduction relay 8. By so doing, the inductance of the wiring largely influencing on surge voltage is made small.

In the voltage measurement circuit according to the first embodiment thus configured, when a key is in a turned-off state, the transistor 12 does not flow current into the electromagnet 8b. Thus, the mechanical contact 8a of the dark-current reduction relay 8 is in an opened state, and so the connection between the second voltage dividing resistor 4 and the third voltage dividing resistor 5 is interrupted. As a result, dark current is prevented from flowing from the battery.

When the key is turned on, the CPU 13 applies an ON signal to the base of the transistor 12. As a result, current is supplied to the electromagnet 8b from the power source of 5 volts which is dropped from the high voltage of the battery. Thus, the mechanical contact 8a is closed.

In response to the closed state of the mechanical contact 8a, current flows from the positive electrode side terminal 1 of the battery to the negative electrode side terminal 2 via the first to fifth voltage dividing resistors 3 to 7 and the dark-current reduction relay 8.

Thus, the divided voltage, equal to or lower than 5 volts, of the total voltage can be taken out from the portion between the second voltage dividing resistor 4 and the third voltage dividing resistor 5, and this divided voltage is subjected to an analog-to-digital conversion by the A/D circuit 11. Then, the digital signal is converted into the optical signal by the photo coupler 15 and sent to the CPU 13. The CPU calculates the terminal voltage of the battery.

When the key is turned on, surge voltage is generated by the same reason explained in relation to the related art. However, according to the first embodiment, the second voltage dividing resistor 4 is disposed on the upstream side of the dark-current reduction relay 8 so as to be close to the dark-current reduction relay as possible. By doing so, the inductance 9B between the upstream side of the dark-current reduction relay 8 and the second voltage dividing resistor 4 is much smaller than the value of the related art. In contrast, the inductance 9C between the downstream side of the dark-current reduction relay 8 and the third voltage dividing resistor 5 is almost same as that of the related art. However, this inductance is small as compared with the inductance 9A. Thus, a total value of the inductance 9B and the inductance 9C between the second voltage dividing resistor 4 and the third voltage dividing resistor 5 becomes much smaller than that of the related art. The electromotive voltage due to the inductance applied between the both ends of each of the second voltage dividing resistor 4 and the third voltage dividing resistor 5 at the time of turning-on of the key becomes small by an amount corresponding to the reduced amount of the inductance.

Accordingly, a resistor having a high withstand voltage is not required to be used as each of the voltage dividing resistors 3 to 7, and hence cost increase can be suppressed.

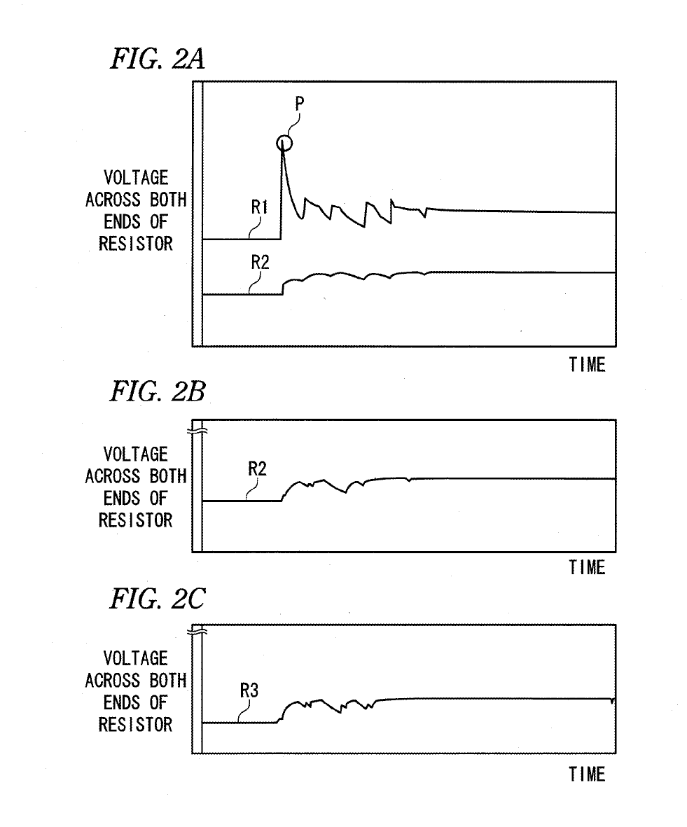

To confirm the aforesaid effects, simulation results of a comparison between the related art and the first embodiment will be shown with reference to FIGS. 2A to 2C.

In each of FIGS. 2A to 2C, an abscissa represents time and an ordinate represents a voltage applied between the both ends of the voltage dividing resistor. FIG. 2A shows a case of the related art and each of FIGS. 2B and 2C shows a case of the first embodiment.

In this simulation, each of the first to fourth voltage dividing resistors is set to have the same resistance value, whilst the fifth voltage dividing resistor is set to have a resistance value much smaller than those of the first to fourth voltage dividing resistors.

In this figure, in the case of the related art, the first to fifth voltage dividing resistors, which are same as those of the first embodiment, are disposed serially in this order between the downstream side of the dark-current reduction relay 8 and the negative electrode terminal of the battery. In FIG. 2A, the first voltage dividing resistor disposed at the most upstream side on the downstream side of the dark-current reduction relay 8 is denoted by R1, and the second voltage dividing resistor disposed just on the downstream side of the first voltage dividing resistor is denoted by R2. These voltage dividing resistors are shown in the same figure.

On the other hand, in the first embodiment, the second voltage dividing resistor 4 disposed just on the upstream side of the dark-current reduction relay 8 is denoted by R2 in FIG. 2B. Further, the third voltage dividing resistor disposed just on the downstream side of the dark-current reduction relay 8 is denoted by R3 in FIG. 2C. These voltage dividing resistors are shown in the different figures separately so as to avoid the overlapping and easily distinguish therebetween. However, the scale is the same between these figures.

As clear from FIG. 2A, in the related art, when the dark-current reduction relay is turned on, the voltage across the both ends of the first voltage dividing resistor R1 closest to the dark-current reduction relay is large and disturbed. The reason is that as the first inductance is large, counter electromotive voltage becomes large just after the turning-on of the dark-current reduction relay 8 and acts on the first voltage dividing resistor R1. A peak value at this time is shown by a portion P surrounded by a circle in the figure. Thus, an expensive voltage dividing resistor with a high withstand voltage is required to be used as the first voltage dividing resistor durable with such the high voltage.

On the other hand, the second voltage dividing resistor R2 is further away from the dark-current reduction relay 8 than the first voltage dividing resistor. Thus, temporal change of the voltage across the both ends of the second voltage dividing resistor is almost half of the voltage across the both ends of the first voltage dividing resistor R1. Therefore, unlike the first voltage dividing resistor R1, the voltage across the both ends of the second voltage dividing resistor does not disturb excessively.

In the first embodiment, the inductance 9B between the second voltage dividing resistor 4 (R2) and the third voltage dividing resistor 5 (R3) is small. Thus, as shown in FIG. 2B, temporal change of the voltage across the both ends of the second voltage dividing resistor 4 (R2), closest to the dark-current reduction relay 8, is almost same degree as that of the second voltage dividing resistor R2 of the related art, that is, almost half degree as that of the first voltage dividing resistor R1 of the related art. The voltage across the both ends of the second voltage dividing resistor does not disturb excessively.

In the first embodiment, the third voltage dividing resistor 5 (R3) is further away from the dark-current reduction relay 8 than the second voltage dividing resistor 4 (R2). Thus, as shown in FIG. 2C, the temporal change of the voltage across the both ends of the third voltage dividing resistor is slightly low as compared with that of the voltage across the both ends of the second voltage dividing resistor 4 (R2) shown in FIG. 2B.

As described above, in the voltage measurement circuit according to the first embodiment, when the dark-current reduction relay 8 is turned on, the voltage across the both ends of the second voltage dividing resistor 4 on the high voltage side close to the dark-current reduction relay 8 becomes small as compared with the related art. Also, the voltage across the both ends of the third voltage dividing resistor 5 just on the downstream side of the dark-current reduction relay 8 becomes small as compared with the related art. Thus, a cheap voltage dividing resistor with a low withstand voltage can be used as each of these voltage dividing resistors.

Incidentally, as each of the first voltage dividing resistor 3, the fourth voltage dividing resistor 6 and the fifth voltage dividing resistor 7 is away from the dark-current reduction relay 8, the voltage across the both ends of each of these voltage dividing resistors is smaller than the voltage across the both ends of each of the second voltage dividing resistor 4 and the third voltage dividing resistor 5, as clear without showing in drawings. Thus, needless to say, each of the first, fourth and fifth voltage dividing resistors is not required to have a high withstand voltage.

In the aforesaid description, the dark-current reduction relay 8 is connected at the center or the portion close to the center of the plurality of voltage dividing resistors 3 to 7. More specifically, the dark-current reduction relay is connected in series between the second voltage dividing resistor 4 and the third voltage dividing resistor 5. However, as explained below, the dark-current reduction relay 8 may be disposed between any adjacent ones of the plurality of voltage dividing resistors 3 to 7.

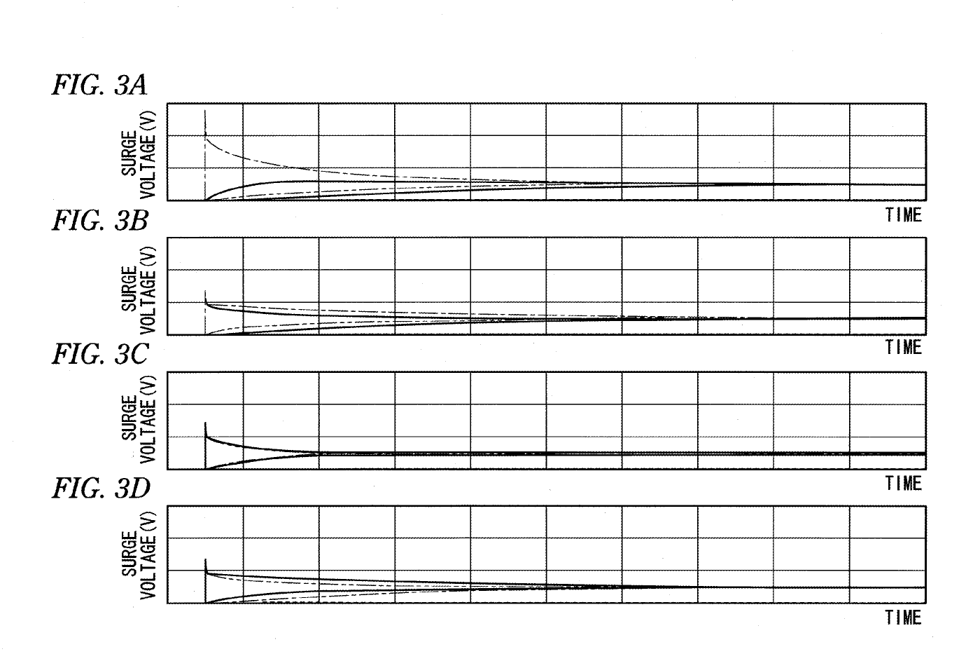

FIGS. 3A to 3D show temporal change of surge voltage at the time of turning-on of the dark-current reduction relay 8. That is, this figure shows, in a comparative manner, the case of the related art wherein the dark-current reduction relay 8 is disposed on the upstream side of all the voltage dividing resistors and cases wherein the disposed position of the dark-current reduction relay 8 between the adjacent ones of the voltage dividing resistors is changed.

FIG. 3A shows the case of the related art. In this figure, an alternate long and short dash line represents the voltage across the both ends of the first voltage dividing resistor R1, a bold steady line represents the voltage across the both ends of the second voltage dividing resistor R2, a thin steady line represents the voltage across the both ends of the third voltage dividing resistor, and an alternate long and two short dashes line represents the voltage across the both ends of the fourth voltage dividing resistor.

In this case, as described above, it will be clear that a quite large surge voltage is applied across the both ends of the first voltage dividing resistor R1 at the time of turning-on of the dark-current reduction relay 8. Thus, an expensive resistor with a high withstand voltage is required as the first voltage dividing resistor durable with such the high voltage.

FIGS. 3B to 3D show modified examples of the first embodiment. In each of these figures, an alternate long and short dash line represents the voltage across the both ends of the first voltage dividing resistor 3, a bold steady line represents the voltage across the both ends of the second voltage dividing resistor 4, a thin steady line represents the voltage across the both ends of the third voltage dividing resistor 5, and an alternate long and two short dashes line represents the voltage across the both ends of the fourth voltage dividing resistor 6.

FIG. 3B shows the voltage across the both ends of each of the first to fourth voltage dividing resistors 3 to 6 in the following case. That is, in this case, the dark-current reduction relay 8 is disposed at the first stage, i.e., between the first voltage dividing resistor 3 and the second voltage dividing resistor 4 in series thereto. The first voltage dividing resistor 3 is disposed on the upstream side of the dark-current reduction relay 8. The third voltage dividing resistor 5, the fourth voltage dividing resistor 6 and the fifth voltage dividing resistor 7 are disposed in series on the downstream side of the second voltage dividing resistor 4.

In this case, it is clear that the surge voltage is equal to or less than the half of the related art.

FIG. 3C shows the voltage across the both ends of each of the first to fourth voltage dividing resistors 3 to 6 in the following case. That is, in this case, the dark-current reduction relay 8 is disposed at the second stage (center), i.e., between the second voltage dividing resistor 4 and the third voltage dividing resistor 5. The first voltage dividing resistor 3 is disposed in series on the upstream side of the second voltage dividing resistor 4 which is on the upstream side of the dark-current reduction relay 8. The fourth voltage dividing resistor 6 and the fifth voltage dividing resistor 7 are disposed in series on the downstream side of the third voltage dividing resistor 5 which is on the downstream side of the dark-current reduction relay 8.

In this case, like the case of the first stage, it is clear that the surge voltage is equal to or less than the half of the related art. The surge voltage disappears earlier as compared with the case of the first stage.

FIG. 3D shows the voltage across the both ends of each of the first to fourth voltage dividing resistors 3 to 6 in the following case. That is, in this case, the dark-current reduction relay 8 is disposed at the third stage, i.e., between the third voltage dividing resistor 5 and the fourth voltage dividing resistor 6. The first voltage dividing resistor 3 and the second voltage dividing resistor 4 are disposed in series on the upstream side of the third voltage dividing resistor 5 which is on the upstream side of the dark-current reduction relay 8. The fifth voltage dividing resistor 7 is disposed in series on the downstream side of the fourth voltage dividing resistor 6 which is on the downstream side of the dark-current reduction relay 8.

In this case, like the cases of the first and send stages, it is clear that the surge voltage is equal to or less than the half of the related art. The surge voltage disappears later as compared with the case of the second stage but almost at the same timing as the case of the first stage.

According to these results, it is clear that, in each case where the dark-current reduction relay 8 is connected between the any adjacent ones of the plurality of voltage dividing resistors, the surge voltage can be reduced greatly as compared with the related art, advantageously. Among these cases, it is clear that the surge voltage can be reduced most effectively when the dark-current reduction relay 8 is connected at the center or the portion close to the center of the plurality of voltage dividing resistors (between the second voltage dividing resistor and the third voltage dividing resistor in the first embodiment using the five voltage dividing resistors).

As explained above, in the voltage measurement circuit according to the first embodiment, the dark-current reduction relay 8 is connected in series between adjacent ones of the plurality of voltage dividing resistors 3 to 7. Thus, at the time of turning-on of the dark-current reduction relay 8, the surge voltage generated across the both ends of each of the voltage dividing resistors 3 to 7 can be suppressed to a low value. As a result, the voltage dividing resistors 3 to 7, withstand voltage of each of which can be reduced by an amount equivalent to the reduced amount of the surge voltage, can be used. Accordingly, the cost of the voltage measurement circuit can be reduced.

The dark-current reduction relay 8 is connected at the center (second stage in the first embodiment) of the plurality of voltage dividing resistors. Thus, the surge voltage can be reduced most effectively.

The voltage measurement circuit according to the first embodiment is optimal for a voltage measurement circuit for a battery of an electric car or a hybrid car (including a plug-in hybrid car).

Although the invention is explained based on the embodiment, the invention is not limited thereto. The invention contains design changes etc. of the embodiment within a range not departing from the gist of the invention.

For example, the number of the voltage dividing resistors is not limited to five of the first embodiment, but may be any of plural number.

The power source is not limited to the battery but may be another type of a power source.

The dark current reduction switch circuit according to the invention is not limited to the dark-current reduction relay 8 of the first embodiment, but may be a circuit switchable between on and off states.

The voltage measurement circuit according to the invention may be applied to other devices and systems in place of an electric car or a hybrid car.

The present application is based on Japanese Patent Application (Japanese Patent Application No. 2012-250890) filed on Nov. 15, 2012, the entirety of which is incorporated herein by reference. All references in this specification are also entirely incorporated herein.

### DESCRIPTION OF REFERENCE NUMERALS AND SIGNS

1. positive electrode side terminal
2. negative electrode side terminal
3. first voltage dividing resistor
4. second voltage dividing resistor
5. third voltage dividing resistor
6. fourth voltage dividing resistor
7. fifth voltage dividing resistor
8. dark-current reduction relay
8.a mechanical contact
8.b electromagnet
9A, 9B inductance
10a to 10j stray capacitance
11. A/D circuit
12. transistor
13. central processing unit
14. divided voltage extraction part
15. photo coupler
16. battery

1. A voltage measurement circuit comprising:
a high-voltage input terminal;
a plurality of voltage dividing resistors which divide a high voltage inputted from the high-voltage input terminal;
a voltage measuring part which measures a voltage reduced to a low voltage by the plurality of voltage dividing resistors; and
a dark current reduction switch circuit which is connected in series between adjacent ones of the plurality of voltage dividing resistors.

2. The voltage measurement circuit according to claim 1, wherein
the dark current reduction switch circuit is connected at a center or a portion close to the center of the plurality of voltage dividing resistors.

3. The voltage measurement circuit according to claim 1, wherein
the high-voltage input terminal is connected to a battery of an electric car or a hybrid car.
